(19) United States
(12) Patent Application Publication
(10) Pub. No.: US 2026/0080918 A1
(43) Pub. Date: Mar. 19, 2026

(54) SEMICONDUCTOR STORAGE DEVICE

(71) Applicant: Kioxia Corporation, Tokyo (JP)

(72) Inventor: Masashi DEGUCHI, Yokkaichi Mie (JP)

(21) Appl. No.: 19/076,744

(22) Filed: Mar. 11, 2025

(30) Foreign Application Priority Data
Sep. 18, 2024 (JP) 2024-160768

(51) Int. Cl. G11C 5/06; G11C 16/04; H10B 43/10; H10B 43/35

(52) U.S. Cl. CPC G11C 5/063; G11C 16/0483; H10B 43/10; H10B 43/35

(57) ABSTRACT

A semiconductor storage device of one embodiment includes a stacked body, a first insulating film, and a second insulating film. In the stacked body, conductive layers are stacked with insulating layers in between. The stacked body has a staircase structure. The first insulating film extends through the stacked body in a terrace region in the staircase structure. The second insulating film is in a step part region of the staircase structure. The second insulating film extends through the stacked body in the stacking direction. The second insulating film has a plane width greater than that of the first insulating film. In some examples, a plurality of first and second insulating films may be provided. In such a case, a disposition density of the second insulating films can be greater than that of the first insulating films.

### CROSS-REFERENCE TO RELATED APPLICATIONS

This application is based upon and claims the benefit of priority from Japanese Patent Application No. 2024-160768, filed Sep. 18, 2024, the entire contents of which are incorporated herein by reference.

### FIELD

Embodiments described herein relate generally to a semiconductor storage device.

### BACKGROUND

In a semiconductor storage device including a stacked body in which a plurality of conductive layers are stacked with insulating layers in between, a staircase structure in which the conductive layers extend stepwise for electrical access to the plurality of conductive layers. In the semiconductor storage device, it is desired to appropriately form the staircase structure.

### BRIEF DESCRIPTION OF THE DRAWINGS

FIG. 1 is a perspective view illustrating a configuration of a semiconductor storage device according to an embodiment.

FIG. 2 is a block diagram of a semiconductor storage device according to an embodiment.

FIG. 3 is a circuit diagram of a memory cell array in an embodiment.

FIG. 4 is a cross-sectional view illustrating the configuration of a memory cell array in an embodiment.

FIG. 5 is a plan view of a memory cell in an embodiment.

FIG. 6 is a plan view illustrating a staircase structure in an embodiment.

FIG. 7 is a cross-sectional view illustrating a staircase structure in an embodiment.

FIG. 8 is a plan view illustrating a staircase structure in a first modification of an embodiment.

FIG. 9 is a plan view illustrating a staircase structure in a second modification of an embodiment.

FIG. 10 is a cross-sectional view illustrating a staircase structure in the second modification of an embodiment.

### DETAILED DESCRIPTION

An object of one embodiment is to provide a semiconductor storage device for which a staircase structure can be appropriately formed.

In general, according to one embodiment, A semiconductor storage device includes a stacked body of conductive layers stacked in a stacking direction with insulating layers in between. The stacked body has a staircase structure in a central region along its longitudinal direction. A first insulating film extends through the stacked body in the stacking direction. The first insulating film is in a terrace part of the staircase structure. A second insulating film is in a region of the stacked body including a step part of the staircase structure. The second insulating film extends through the stacked body in the stacking direction and has a minimum plane width that is greater than a minimum plane width of the first insulating film.

Hereinafter, a semiconductor storage device according to certain example embodiments will be described with reference to the attached drawings. These example embodiments do not limit the present disclosure.

### EMBODIMENT

A semiconductor storage device according to an embodiment includes a stacked body in which a plurality of conductive layers are stacked with insulating layers in between, the stacked body includes a staircase structure in which the plurality of conductive layers extend stepwise in order to permit electrical access to each of the individual conductive layers. In the embodiment, measures are taken to permit the staircase structure to be appropriately formed.

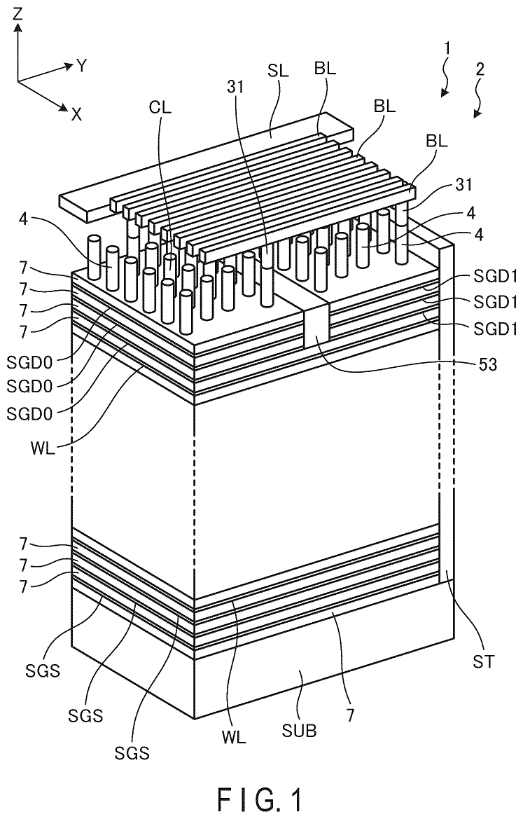

A semiconductor storage device 1 can be configured as illustrated in FIG. 1. FIG. 1 schematically illustrates a configuration of a memory cell array 2 included in the semiconductor storage device 1 according to a first embodiment. The semiconductor storage device 1 is a NAND type nonvolatile memory including three-dimensionally disposed memory cells. In the following description, a direction perpendicular to a surface of a substrate SUB is referred to as a Z direction, and two directions within a plane perpendicular to the Z direction are referred to as an X direction and a Y direction.

As illustrated in FIG. 1, the semiconductor storage device 1 includes select gates SGS, word lines WL, and select gates SGD. The select gates SGS is stacked on the substrate SUB with an interlayer insulating film 7 in between. In an example in FIG. 1, three layers of select gates SGS are provided. The word lines WL are stacked above the select gates SGS with an interlayer insulating film 7 in between. In the following, a select gate SGD refers to the plurality of select gates that may be included in the same layer but are divided from one another. In the example in FIG. 1, select gates SGD0 and SGD1, which are divided from one another in the Y direction are illustrated. The select gate SGD is stacked above the word lines WL with the interlayer insulating film 7 in between. Each select gate SGS, word line WL, and select gate SGD are in a planar shape extending in the X direction and the Y direction.

In FIG. 1, the select gate SGD, the word line WL, and the select gate SGS are segmented in the Y direction by a slit ST, which comprises an insulating material. The slit ST is provided on the substrate SUB, and extends in the X direction and the Z direction.

The select gate SGD is segmented in the Y direction by an insulating film 53, for example. The insulating film 53 is provided above (+Z side) the word lines WL, and extends in the X direction and the Z direction. Therefore, the select gate SGD0 and the select gate SGD1 are disposed side by side in the Y direction. In FIG. 1, three layers of the select gates SGD0 and SGD1 are provided, respectively.

The substrate SUB may be formed of a semiconductor material, such as silicon. The select gate SGS, the word line WL, and the select gate SGD may be formed of a metal material such as tungsten (W). The interlayer insulating film 7 and the insulating film 53 may be formed of an insulator material such as silicon oxide.

The semiconductor storage device 1 further includes a plurality of columnar bodies 4. The columnar bodies 4 pass through the select gate SGS, the word line WL, and the select gate SGD, and extend in the Z direction. The semiconductor storage device 1 further includes a plurality of bit lines BL and a source line SL provided above the uppermost select gate SGD.

The columnar bodies 4 are each electrically connected to one of the bit lines BL via a contact plug 31. For example, one of the columnar bodies 4 sharing the select gate SGD0 and one of the columnar bodies 4 sharing the select gate SGD1 can be electrically connected to the same bit line BL.

Note that, in FIG. 1, an interlayer insulating film that is provided between the select gate SGD and the bit lines BL is omitted from the depiction in order to simplify illustration for clarity of other aspects.

In a case of a semiconductor storage device (e.g., a memory device) having a three-dimensional structure like the semiconductor storage device 1, a part where a word line WL and a columnar body 4 intersect functions as a memory cell, and the memory cell array 2 in which the plurality of memory cells are three-dimensionally arrayed is configured. In addition, a part where a select gate SGS and a columnar body 4 intersect functions as a select gate on a source side, and a part where select gates SGD0 and SGD1 intersect a columnar body 4 is a select gate on a drain side. In the semiconductor storage device 1, by increasing a stacking number of the word lines WL in the stacked body, it is possible to increase a storage capacity without utilizing a finer patterning technique.

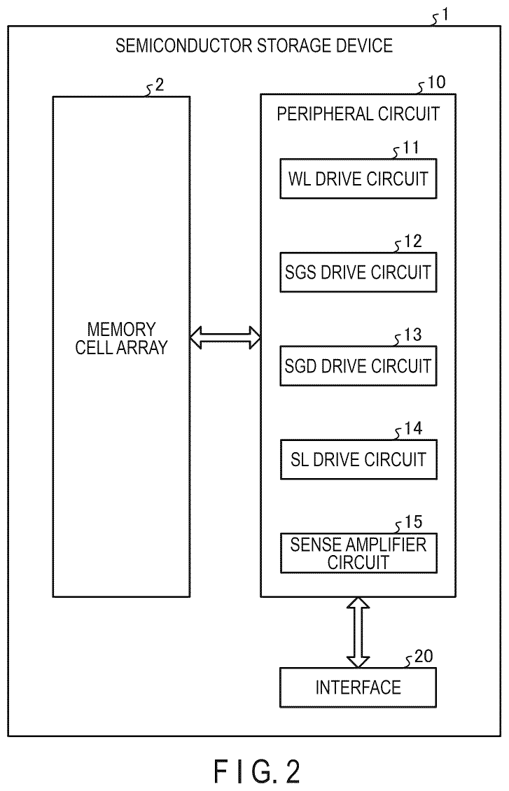

FIG. 2 is a block diagram illustrating a configuration of the semiconductor storage device 1.

As illustrated in FIG. 2, the semiconductor storage device 1 includes the memory cell array 2, a peripheral circuit 10, and an interface 20. The peripheral circuit 10 includes a WL drive circuit 11, an SGS drive circuit 12, an SGD drive circuit 13, an SL drive circuit 14, and a sense amplifier circuit 15.

The WL drive circuit 11 controls an applied voltage to the word line WL, and the SGS drive circuit 12 controls a voltage applied to the select gate SGS. The SGD drive circuit 13 controls a voltage applied to the select gate SGD, and the SL drive circuit 14 controls a voltage applied to the source line SL. The sense amplifier circuit 15 determines read data according to a signal from a selected memory cell.

The peripheral circuit 10 controls operations of the semiconductor storage device 1 based on an instruction sent from outside the device via the interface 20 (for example, a memory controller of a memory system in which the semiconductor storage device 1 is installed or incorporated by sending an instruction or command to the semiconductor storage device 1). For example, upon receiving a write instruction to perform a writing, the peripheral circuit 10 selects the memory cell at the address to which writing has been instructed using the SGS drive circuit 12, the SGD drive circuit 13, and the WL drive circuit 11, and then applies a voltage to the selected memory cell according the instructed data to be written. Upon receiving a read instruction, the peripheral circuit 10 selects the memory cell at the instructed address in the memory cell array 2 using the SGS drive circuit 12, the SGD drive circuit 13, and the WL drive circuit 11, then determines the data read from the selected memory cell from according to a signal received by the sense amplifier circuit 15. The read data is then output by the peripheral circuit 10 via the interface 20 to the outside (e.g., to the associated memory controller).

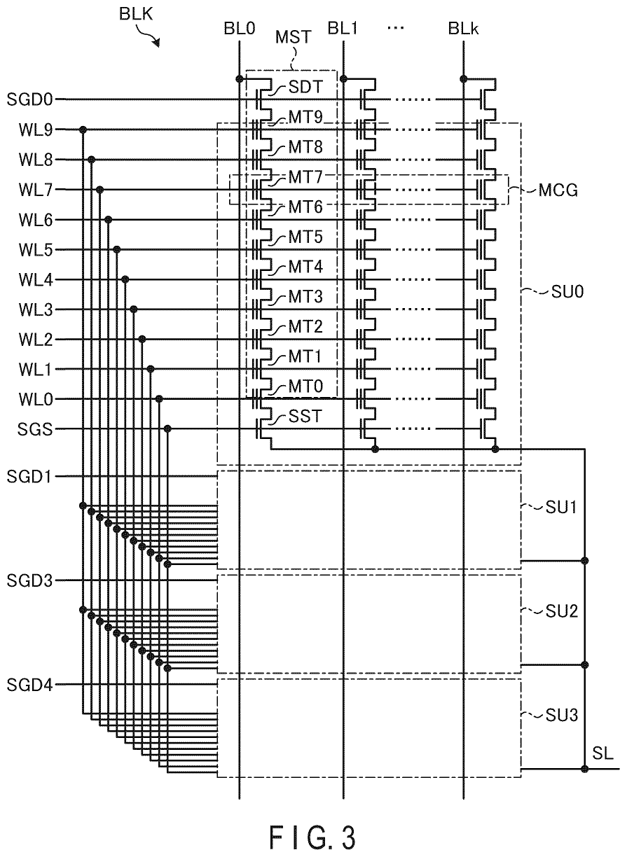

Next, the configuration of the memory cell array 2 will be described using FIG. 3. FIG. 3 is a circuit diagram illustrating the configuration of the memory cell array 2 included in the semiconductor storage device 1.

The memory cell array 2 includes a plurality of blocks BLK each of which is a set of a plurality of memory cells MT. A memory cell MT may also be referred to as a memory cell transistor.

Each block BLK includes a plurality of string units SU0, SU1, SU2, and SU3, which are sub-sets of the memory cells MT associated with the word lines WL and the bit lines BL. The string units SU0-SU3 each include a plurality of memory strings MST, which formed are memory cells MT connected in series along the same bit line BL. Note that the number of the memory strings MST in the string units SU0-SU3 is arbitrary and may vary from that depicted.

The plurality of string units SU0, SU1, SU2, and SU3 correspond to a plurality of select gate lines SGD0, SGD1, SGD3, and SGD4. Each of the plurality of string units SU0, SU1, SU2, and SU3 share the select gate line SGS and function as a drive unit in each block BLK. Each string unit SU may be driven by use of the corresponding select gate line SGD and the select gate line SGS. In addition, each string unit SU includes a plurality of memory strings MST.

Each memory string MST includes a pair of select transistors SDT and SST and ten memory cells MT (MT0-MT9). Each memory cell MT includes a control gate and a charge storage layer and holds/stores data in a nonvolatile manner. The ten memory cells MT (MT0-MT9) are connected in series between a source of the select transistor SDT and a drain of the select transistor SST. Note that the number of the memory cells MT in the memory string MST is not limited to ten.

The gate of the select transistor SDT in each string unit SU is connected to a corresponding select gate line SGD. The gate of the select transistor SST in each string unit SU is connected to the select gate line SGS (a common select gate line), for example.

The drain of the select transistor SDT of each memory string MST in each string unit SU is connected to different bit lines BL0-BLk (where k is an integer of 2 or more), respectively. The bit lines BL0-BLk connect to a different memory string MST within each string unit SU but are shared in common across the plurality of blocks BLK. Further, a source of each select transistor SST is connected in common to the source line SL (a common source line).

That is, each string unit SU is a set of the memory strings MST connected to the different bit lines BL0-BLk but connected to the same select gate line SGD. Each block BLK is a set of the plurality of string units SU0-SU3 having the same word lines WL in common. The memory cell array 2 is a set of the plurality of blocks BLK sharing the same bit lines BL0-BLk in common.

A group of memory cells MT sharing a word line WL may be referred to as a “memory cell group MCG”, a memory cell group MCG is a minimum unit size of memory cells to which a predetermined voltage (for example, a write voltage or a read voltage) can be applied all together via the same word line WL.

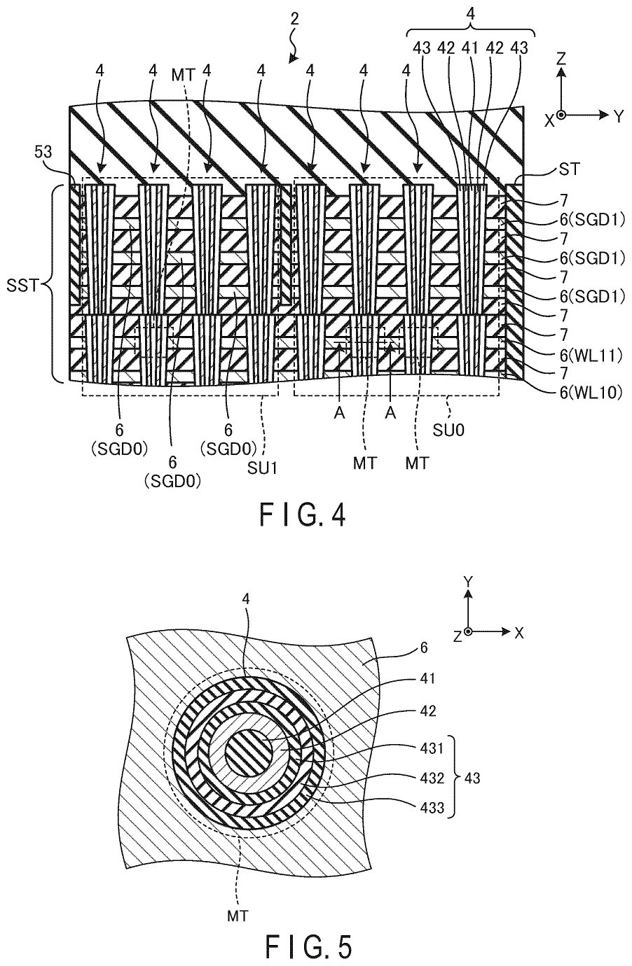

Next, a specific configuration of the memory cell array 2 will be described using FIG. 4 and FIG. 5. FIG. 4 is a YZ cross-sectional view illustrating the configuration of the memory cell array 2. FIG. 5 is an XY plan view illustrating the configuration of the memory cell MT, and illustrates an XY plane section taken at the A-A line in FIG. 4.

The memory cell array 2 is a three-dimensional memory cell array configured with a two-dimensional arraying of columnar bodies 4 arranged in an XY plane, with the columnar bodies 4 passing through multiple layers of word lines WL from the +Z side of the substrate SUB.

In the memory cell array 2, a stacked body SST in which conductive layers 6 and the insulating layers 7 are alternately and repeatedly stacked is formed. In the stacked body SST, each conductive layer 6 may be formed of a conductive material (for example, a metal such as tungsten). Each insulating layer 7 may be formed of an insulator material (for example, a semiconductor oxide such as silicon oxide). Most of the conductive layers 6 function as a word line WL, however, certain conductive layers 6 on the +Z side function as the select gate line SGD, and certain conductive layers 6 on a-Z side function as the select gate line SGS.

In the memory cell array 2, the plurality of memory cells MT are formed where the word lines WL and columnar bodies 4 intersect. The plurality of select transistors SDT are formed where the select gate line SGD and columnar bodies 4 intersect. The select transistors SST are formed where the select gate line SGS and columnar bodies 4 intersect. As illustrated in FIG. 5, a columnar body 4 includes a core insulating film 41, a semiconductor channel 42, and an insulating film 43. The core insulating film 41 may be formed of an insulator material (for example, silicon oxide). The semiconductor channel 42 has a generally cylindrical shape that surrounds the core insulating film 41 and extends along a center axis of the columnar body 4.

The semiconductor channel 42 includes a channel region (active region) in the memory string MST, and can be formed of an undoped semiconductor material (for example, polysilicon).

The insulating film 43 is disposed between the conductive layers 6 and the semiconductor channel 42, and surrounds the semiconductor channel 42 in a planar view. The insulating film 43 covers a side face of the semiconductor channel 42. The insulating film 43 is configured to have charge storage capability at a part disposed between the conductive layers 6 and the semiconductor channel 42.

As illustrated in FIG. 5, the insulating film 43 may be formed of a three-layer structure of a tunnel insulating film 431/a charge storage film 432/a block insulating film 433 in order from the side of the semiconductor channel 42. The tunnel insulating film 431 may be formed of an oxide material (for example, silicon oxide). The charge storage film 432 may be formed of a nitride material (for example, silicon nitride). The block insulating film 433 may be formed of an oxide material (for example, silicon oxide, metal oxide, or a multiple layers of such material).

That is, the insulating film 43 may have an ONO type three-layer structure in which the charge storage film is held between a pair of insulating films (the tunnel insulating film and the block insulating film) at the position (the memory cell MT) disposed between the conductive layers 6 (the word lines WL) and the semiconductor channel 42. The insulating film 43 may be formed of a single-layer structure of a gate insulating film at the position (the select transistor SDT) disposed between the conductive layers 6 (the select gate lines SGD) and the semiconductor channel 42. The gate insulating film may be formed of an oxide material (for example, silicon oxide).

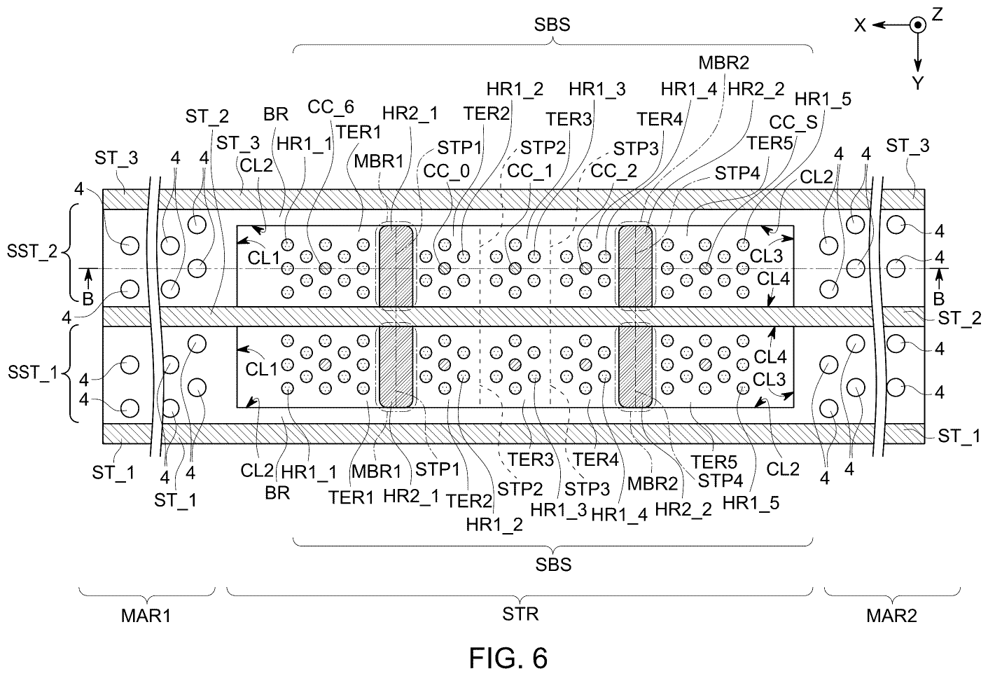

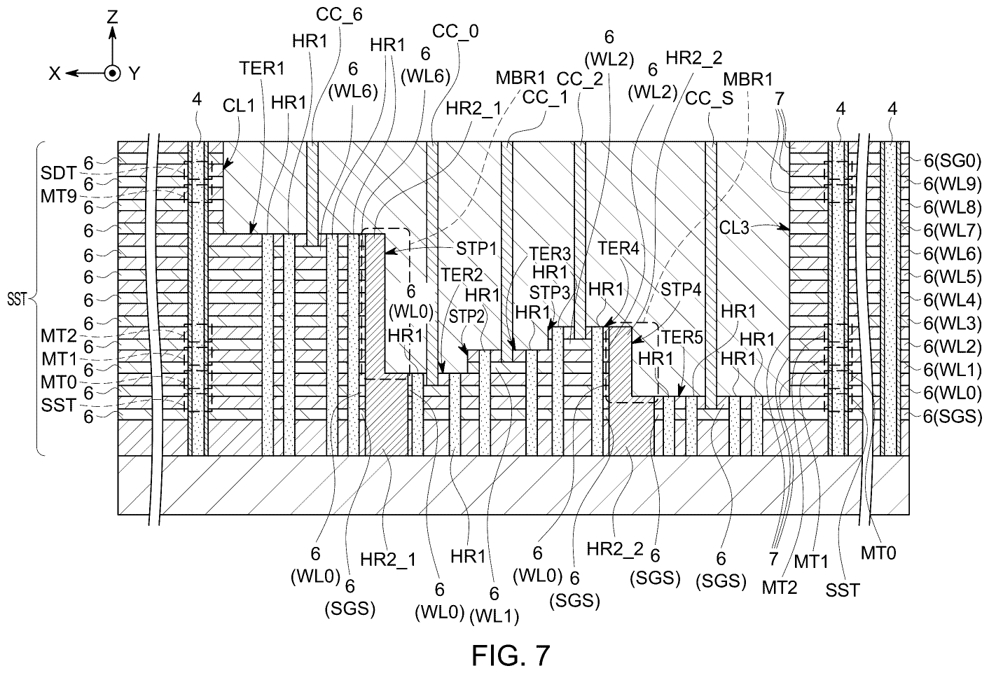

As illustrated in FIG. 6 and FIG. 7, each stacked body SST may include a staircase structure SBS near a center region in a longitudinal direction. FIG. 6 is an XY plan view illustrating the staircase structure SBS. FIG. 7 is an XZ sectional view illustrating the staircase structure SBS, and illustrates an XZ cross section in the case of cutting FIG. 6 at the B-B line.

The semiconductor storage device 1 may include a plurality of stacked bodies SST_1 and SST_2. The plurality of stacked bodies SST_1 and SST_2 are arrayed in the Y direction. The plurality of stacked bodies SST_1 and SST_2 are segmented in the Y direction by the slit ST.

The stacked body SST_1 has a roughly rectangular shape with the X direction as the longitudinal direction in an XY planar view. The stacked body SST_1 is segmented from the stacked body SST_2 via a slit ST_2 on a-Y side. The stacked body SST_1 may be segmented from another stacked body SST via a slit ST_1 on a +Y side.

The stacked body SST_2 has a roughly rectangular shape with the X direction as the longitudinal direction in the XY planar view. The stacked body SST_2 is segmented from the stacked body SST_1 via the slit ST_2 on the +Y side. The stacked body SST_2 may be segmented from another stacked body SST via a slit ST_3 on the −Y side.

Each stacked body SST includes a staircase region STR at the center along the X direction and also includes memory cell array regions MAR1 and MAR2 on the ends in the X direction of the staircase region STR. In the staircase region STR, the staircase structure SBS in which the respective conductive layers 6 extend stepwise is provided. Thus, the respective conductive layers 6 can be electrically accessible (e.g., contacted).

In the memory cell array region MAR1, on a +X side of each stacked body SST, columnar bodies 4 are arrayed in the XY directions, and an array of memory cells MT is formed in XYZ directions at the plurality of positions where the conductive layers 6 (the word lines WL) and the columnar bodies 4 intersect. An array in the XY directions of the plurality of select transistors SDT is formed at the plurality of positions where the conductive layer 6 (the select gate line SGD) on the +Z side and the plurality of columnar bodies 4 intersect. An array in the XY directions of the plurality of select transistors SST is formed at the plurality of positions where the conductive layer 6 (the select gate line SGS) on the −Z side and the plurality of columnar bodies 4 intersect.

In the memory cell array region MAR2 on a −X side of each stacked body SST, the plurality of columnar bodies 4 are arrayed in the XY directions, and the array of memory cells MT is formed at the positions where the conductive layers 6 (the word lines WL) and the columnar bodies 4 intersect. The array of the plurality of select transistors SDT is formed at the positions where a conductive layer 6 (the select gate line SGD) on the +Z side and the columnar bodies 4 intersect. The array of the select transistors SST is formed at the positions where conductive layers 6 (the select gate line SGS) on the-Z side and the columnar bodies 4 intersect.

In the staircase region STR of each stacked body SST, the staircase structure SBS and a bridge structure BR are provided. The staircase structure SBS and the bridge structure BR are adjacent to each other in the Y direction. The staircase structure SBS is adjacent to the memory cell array region MAR1 on the +X side and to the memory cell array region MAR2 on the-X side. The bridge structure BR connects the conductive layers 6 in the memory cell array region MAR1 and the conductive layers 6 in the memory cell array region MAR2 via a connective structure at a Z height matching each conductive layer 6. Thus, at the Z height of each conductive layer 6, the conductive layer 6 in the memory cell array region MAR1 and the conductive layer 6 in the memory cell array region MAR2 are electrically connected via the bridge structure BR.

In the stacked body SST_1, the staircase structure SBS is provided on the −Y side, and the bridge structure BR is provided on the +Y side. In the stacked body SST_2, the staircase structure SBS is provided on the +Y side, and the bridge structure BR is provided on the −Y side. The staircase structure SBS of the stacked body SST_1 and the staircase structure SBS of the stacked body SST_2 are thus adjacent to one another in the Y direction via the slit ST_2.

The staircase structure SBS includes a plurality of terrace parts TER1-TER5, a plurality of step parts STP1-STP4, and a plurality of cliff parts CL1-CL4. The plurality of cliff parts CL1-CL4 have a roughly rectangular shape in the XY planar view, and define a boundary between the staircase structure SBS and its periphery. On an inner side of the boundary, in the XY planar view, the terrace part TER1, the step part STP1, the terrace part TER2, the step part STP2, the terrace part TER3, the step part STP3, the terrace part TER4, the step part STP4, and the terrace part TER5 are disposed in this order from the memory cell array region MAR1 in the −X direction.

In each stacked body SST, by the staircase structure SBS, as illustrated in FIG. 7, the plurality of conductive layers 6 extend stepwise.

In the terrace part TER1, a surface on the +Z side (upper side) has the Z height corresponding to a conductive layer 6 (a word line WL6). The conductive layer 6 (the word line WL6) is thus extended by the terrace part TER1. A contact plug CC_6 extending in the Z direction is connected to a +Z surface of the extended conductive layer 6 (the word line WL6).

In the terrace part TER2, a surface on the +Z side has the Z height corresponding to another conductive layer 6 (a word line WL0). The conductive layer 6 (the word line WL0) is extended by the terrace part TER2. A contact plug CC_0 extending in the Z direction from the +Z side is connected to the extended upper surface of the word line WL0.

The conductive layer 6 (the word line WL1) is extended by the terrace part TER3. A contact plug CC_1 extending in the Z direction from the +Z side is connected to the extended upper surface of the word line WL1.

The conductive layer 6 (the word line WL2) is extended by the terrace part TER4. A contact plug CC_2 extending in the Z direction from the +Z side is connected to the extended upper surface of the word line WL2.

The conductive layer 6 (the select gate line SGS) is extended by the terrace part TER5. A contact plug CC_S extending in the Z direction from the +Z side is connected to the extended upper surface of the select gate line SGS.

Of the plurality of step parts STP1-STP4, the step parts STP1 and STP4 designated with dashed lines in FIG. 6 have a Z height greater than a disposition pitch in the Z direction of the conductive layers 6, as illustrated in FIG. 7. The step parts STP1 and STP 4 have a Z height which can correspond to N times the disposition pitch in the Z direction of the conductive layers 6. Here, N is an integer of 2 or more. The step parts STP1 and STP4 may be referred to as multi-stage step parts.

Vicinity regions where the multi-stage step parts STP1 and STP4 are disposed are referred to as multi-stage boundary regions MBR. A multi-stage boundary region MBR1 includes the multi-stage step part STP1 on the inner side and spreads in the X direction. A multi-stage boundary region MBR2 includes the multi-stage step part STP4 on the inner side, and spreads in the X direction.

Of the plurality of step parts STP1-STP4, the step parts STP2 and STP3 illustrated with dotted lines in FIG. 6 have a Z height which corresponds to one times the disposition pitch in the Z direction of the conductive layers 6. The step parts STP2 and STP3 may be referred to as single-stage step parts.

The staircase structure SBS further includes a plurality of insulating films HR1 and a plurality of insulating films HR2.

The plurality of insulating films HR1 are arrayed in the XY directions in the terrace parts TER in the staircase structure SBS. The insulating films HR1 each extend through the stacked body SST in the Z direction in the terrace parts TER. Thus, the plurality of insulating films HR1 can structurally reinforce the terrace parts TER.

In the terrace part TER1, a plurality of insulating films HR1_1 are arrayed in the XY directions around the contact plug CC_6. FIG. 6 illustrates the configuration in which insulating films HR1_1 are arrayed in a honeycomb shape. Each insulating film HR1_1 has the same minimum plane width. Each insulating film HR1_1 has the same maximum plane width.

In the terrace part TER2, a plurality of insulating films HR1_2 are arrayed in the XY directions around the contact plug CC_0. FIG. 6 illustrates a configuration in which the insulating films HR1_2 are arrayed in a honeycomb shape. Each insulating film HR1_2 has the same minimum plane width. Each insulating film HR1_2 has the same maximum plane width.

In the terrace part TER3, a plurality of insulating films HR1_3 are arrayed in the XY directions around the contact plug CC_1. FIG. 6 illustrates a configuration in which insulating films HR1_3 are arrayed in a honeycomb shape. Each insulating film HR1_3 has the same minimum plane width. Each insulating film HR1_3 has the same maximum plane width.

In the terrace part TER4, a plurality of insulating films HR1_4 are arrayed in the XY directions around the contact plug CC_2. FIG. 6 illustrates the configuration in which the plurality of insulating films HR1_4 are arrayed in the honeycomb shape. Each insulating film HR1_4 has the same minimum plane width. Each insulating film HR1_4 has the same maximum plane width.

In the terrace part TER5, a plurality of insulating films HR1_5 are arrayed in the XY directions around the contact plug CC_S. FIG. 6 illustrates the configuration in which the plurality of insulating films HR1_5 are arrayed in the honeycomb shape. Each insulating film HR1_5 has the same minimum plane width. Each insulating film HR1_5 has the same maximum plane width.

The plurality of insulating films HR2 are disposed in the multi-stage boundary regions MBR, respectively.

In the multi-stage boundary region MBR1, one insulating film HR2_1 having a minimum plane width greater than that of the insulating film HR1 is disposed. When the insulating film HR1 is roughly circular in the XY planar view, its diameter corresponds to the minimum plane width, and when the insulating film HR1 is roughly elliptic in the XY planar view, the minor axis corresponds to the minimum plane width. The insulating film HR2_1 covers the multi-stage step part STP1 and extends in a roughly rectangular shape with the Y direction as the longitudinal direction, and the X width corresponds to the minimum plane width. The X width of the insulating film HR2_1 is greater than the diameter (or the minor axis) of the insulating film HR1, and the X width of the insulating film HR2_1 may be greater than or equal to twice the diameter (or the minor axis) of the insulating film HR1.

In the multi-stage boundary region MBR1, one insulating film HR2_1 having a maximum plane width greater than that of the insulating film HR1 is disposed. When the insulating film HR1 is roughly circular in the XY planar view, the diameter corresponds to the maximum plane width, and when the insulating film HR1 is roughly elliptic in the XY planar view, the major axis corresponds to the maximum plane width. The insulating film HR2_1 covers the multi-stage step part STP1 and extends in the roughly rectangular shape with the Y direction as the longitudinal direction in the XY planar view, and the Y width corresponds to the maximum plane width. The Y width of the insulating film HR2_1 is greater than the diameter (or the major axis) of the insulating film HR1, and the Y width of the insulating film HR2_1 may be greater than or equal to twice the diameter (or the major axis) of the insulating film HR1. The Y width of the insulating film HR2_1 may be roughly equal to the Y width of the staircase structure SBS.

The insulating film HR2_1 illustrated in FIG. 7 extends through the stacked body SST in the Z direction in the multi-stage boundary region MBR1. Thus, the insulating film HR2_1 can structurally reinforce the multi-stage boundary region MBR1. In addition, the insulating film HR2_1 can suppress electrical leakage between the conductive layers 6 that are adjacent in the Z direction near the multi-stage boundary region MBR1.

For the insulating film HR2_1, a surface on the +Z side of a part on the +X side forms a part of the terrace part TER1, a surface on the +Z side of a part on the −X side forms a part of the terrace part TER2, and a surface on the −X side of a part at the center in the X direction forms the multi-stage step part STP1. While the multi-stage step part STP1 extends in a YZ direction, an extension surface on the −Z side thereof is positioned within the insulating film HR2_1.

That is, a structure is such that the multi-stage step part STP1 and the vicinity of the extension surface are filled with the insulating film HR2_1. This structure is suitable for preventing a pattern defect of the conductive layers 6.

For example, in manufacturing, a stacked body SSTa in which sacrificial layers 6a and the insulating layers 7 are alternately and repeatedly stacked is formed, and the multi-stage step part STP1 in the staircase structure is formed by applying a staircase working process of forming many steps with a small number of times of working. Thereafter, by a dry-etching process, holes for the insulating films HR1 are formed in the terrace part, and a hole for the insulating film HR2_1 is formed in the multi-stage step part STP1.

At that time, the minimum plane width of the hole for the insulating film HR2_1 is greater than the minimum plane width of the hole for the insulating film HR1. The maximum plane width of the hole for the insulating film HR2_1 is greater than the maximum plane width of the holes for the insulating films HR1. Ions reflected in the multi-stage step part STP1 remain inside the hole for the insulating film HR2_1, and erroneous etching of the sacrificial layers 6a can be prevented.

Thereafter, the insulating films HR1 are embedded in the holes for the insulating films HR1, and the insulating film HR2_1 is embedded in the hole for the insulating film HR2_1. The sacrificial layers 6a are removed, and the conductive layers 6 are embedded in gaps formed by removing of the sacrificial layers 6a while the insulating films HR1 and the insulating film HR2_1 function as structural reinforcing materials.

At that time, since the erroneous etching of the sacrificial layers 6a can be prevented, pattern defects in corresponding the conductive layers 6 can be prevented.

For example, with a side face on the +X side of the insulating film HR2_1 illustrated in FIG. 7, the conductive layer 6 (SGS), the conductive layers 6 (WL0 to WL6) are all in contact, indicating that there is no chipping or the like of a pattern of the conductive layers 6. With a side face on the-X side of the insulating film HR2_1, the conductive layer 6 (SGS) and the conductive layer 6 (WL0) are both in contact, indicating that there is no chipping or the like of the pattern of the conductive layers 6.

In the multi-stage boundary region MBR2 illustrated in FIG. 6, one insulating film HR2_2 having a minimum plane width greater than that of the insulating film HR1 is disposed. The insulating film HR2_2 covers the multi-stage step part STP4 and extends in a roughly rectangular shape with the Y direction as the longitudinal direction in the XY planar view, and the X width corresponds to the minimum plane width. The X width of the insulating film HR2_2 is greater than the diameter (or the minor axis) of the insulating film HR1. The X width of the insulating film HR2_2 may be greater than or equal to twice the diameter (or the minor axis) of the insulating film HR1.

In the multi-stage boundary region MBR2, one insulating film HR2_2 having the maximum plane width greater than that of the insulating film HR1 is disposed. The insulating film HR2_2 covers the multi-stage step part STP4 and extends in the roughly rectangular shape with the Y direction as the longitudinal direction in the XY planar view, and the Y width corresponds to the maximum plane width. The Y width of the insulating film HR2_2 is greater than the diameter (or the major axis) of the insulating film HR1, and the Y width of the insulating film HR2_2 may be greater than or equal to twice the diameter (or the major axis) of the insulating film HR1. The Y width of the insulating film HR2_2 may be roughly equal to the Y width of the staircase structure SBS.

The insulating film HR2_2 illustrated in FIG. 7 extends through the stacked body SST in the Z direction in the multi-stage boundary region MBR2. Thus, the insulating film HR2_2 can structurally reinforce the multi-stage boundary region MBR2. In addition, the insulating film HR2_2 can suppress the electrical leakage between the conductive layers 6 that are adjacent in the Z direction near the multi-stage boundary region MBR2.

For the insulating film HR2_2, a surface on the +Z side of a part on the +X side forms a part of the terrace part TER4, a surface on the +Z side of a part on the −X side forms a part of the terrace part TER5, and a surface on the −X side of a part at the center in the X direction forms the multi-stage step part STP4. While the multi-stage step part STP4 extends in the YZ direction, the extension surface on the −Z side thereof is positioned within the insulating film HR2_2.

That is, the structure is such that the multi-stage step part STP4 and the vicinity of the extension surface are filled with the insulating film HR2_2. This structure is suitable for preventing pattern defects in the conductive layers 6.

For example, in manufacturing, the stacked body SSTa in which the sacrificial layers 6a and the insulating layers 7 are alternately and repeatedly stacked is formed, and the multi-stage step part STP4 in the staircase structure SBS is formed by applying the staircase working process. Thereafter, by a dry-etching process, holes for the insulating films HR1 are formed in the terrace part, and a hole for the insulating film HR2_2 is formed in the multi-stage step part STP4.

At that time, the minimum plane width of the hole for the insulating film HR2_2 is greater than the minimum plane width of the hole for the insulating film HR1. The maximum plane width of the hole for the insulating film HR2_2 is greater than the maximum plane width of the hole for the insulating film HR1. Ions reflected in the multi-stage step part STP4 remain inside the hole for the insulating film HR2_2, and the erroneous etching of the sacrificial layers 6a can be prevented.

Thereafter, the insulating films HR1 are embedded in the holes for the insulating films HR1, and the insulating film HR2_2 is embedded in the hole for the insulating film HR2_2. The sacrificial layers 6a are removed, and the conductive layers 6 are embedded in gaps formed by removing the sacrificial layers 6a in a state where the insulating films HR1 and the insulating film HR2_2 function as the structural reinforcing materials.

At that time, since the erroneous etching of the sacrificial layers 6a can be prevented, pattern defects in the corresponding conductive layers 6 can be prevented.

For example, with a side face on the +X side of the insulating film HR2_2 illustrated in FIG. 7, the conductive layer 6 (SGS), the conductive layers 6 (WL0 to WL2) are all in contact, indicating that there is no chipping or the like of the pattern of the conductive layers 6. With a side face on the −X side of the insulating film HR2_2, the conductive layer 6 (SGS) is in contact, indicating that there is no chipping or the like of the pattern of the conductive layers 6.

As above, one insulating film HR2 having a minimum plane width greater than that of the insulating film HR1 is disposed in each multi-stage boundary region MBR of the staircase structure SBS. The structure is such that the multi-stage step part STP and the vicinity of the extension surface are filled with the insulating film HR2. This structure is suitable for preventing pattern defects in the conductive layers 6. Thus, it is possible to provide a semiconductor storage device 1 in which the staircase structure SBS can be more appropriately formed.

Note that one insulating film HR2 having a minimum plane width greater than that of the insulating film HR1 may be disposed in some of the multi-stage boundary regions MBR among the plurality of multi-stage boundary regions MBR1 and MBR2 in the staircase structure SBS. For example, in manufacturing, when the erroneous etching of the sacrificial layers 6a is unlikely to occur in the multi-stage boundary region MBR2 as compared with the multi-stage boundary region MBR1, the insulating film HR2 may be disposed in the multi-stage boundary region MBR1 and the insulating film HR1 may be disposed instead of the insulating film HR2 in the multi-stage boundary region MBR2. Alternatively, the insulating film HR2 may be disposed in the multi-stage boundary region MBR1 and no insulating film may be disposed in the multi-stage boundary region MBR2.

Alternatively, one insulating film HR2 having a minimum plane width greater than that of the insulating film HR1 may be disposed in the vicinity of the single-stage step parts STP2 and STP3, in addition to the vicinity of the multi-stage step parts STP1 and STP4.

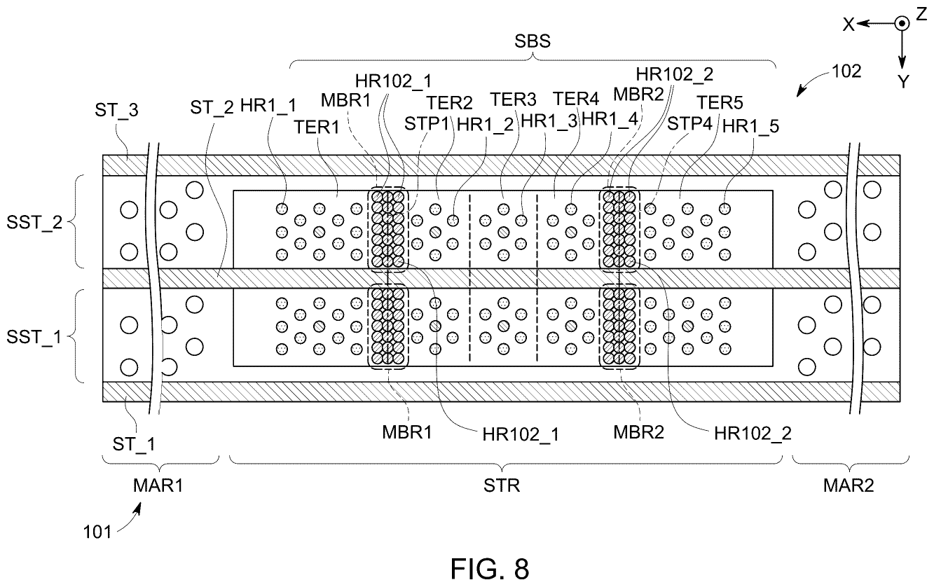

Alternatively, as a first modification of the embodiment, in a memory cell array 102 of a semiconductor storage device 101, as illustrated in FIG. 8, a disposition density of insulating films HR102 in the vicinity of the multi-stage step parts STP may be higher than that of the insulating films HR1 in the terrace parts TER. FIG. 8 is an XY plan view illustrating the staircase structure SBS in the first modification of the embodiment.

In the staircase structure SBS in the semiconductor storage device 101 illustrated in FIG. 8, the disposition density of a plurality of insulating films HR102_1 in the multi-stage boundary region MBR1 is higher than the disposition density of the insulating films HR1_1-HR1_5 in the terrace parts TER1-TER5.

For example, in the multi-stage boundary region MBR1, the plurality of insulating films HR102_1 are planarly joined and disposed. The plurality of insulating films HR102_1 may be disposed so as to be arrayed in a grid shape in the XY direction in the multi-stage boundary region MBR1. Each insulating film HR102_1 may be joined with another insulating film HR102_1 adjacent in the XY direction as a partially continuous film. Thus, the plurality of insulating films HR102_1 are joined and disposed so as to cover the multi-stage step part STP1.

Among the plurality of insulating films HR102_1 illustrated in FIG. 8, a surface on the +Z side of the insulating film HR102_1 on the +X side forms a part of the terrace part TER1, a surface on the +Z side of the insulating film HR102_1 on the −X side forms a part of the terrace part TER2, and a surface on the −X side of the insulating film HR102_1 at the center in the X direction forms the multi-stage step part STP1. While the multi-stage step part STP1 extends in the YZ direction, the extension surface on the −Z side thereof is mostly positioned within the insulating films HR102_1.

That is, the structure is such that the multi-stage step part STP1 and the vicinity of the extension surface are mostly filled with the insulating films HR102_1. This structure is suitable for preventing pattern defects in the conductive layers 6.

For example, in manufacturing, the stacked body SSTa in which the sacrificial layers 6a and the insulating layers 7 are alternately and repeatedly stacked is formed, and the multi-stage step part STP1 in the staircase structure is formed by applying a staircase working process. Thereafter, by a dry-etching process, holes for the insulating films HR1 are formed in the terrace part, and holes for the insulating films HR102_1 are formed in the multi-stage step part STP1.

At that time, the disposition density of the holes for the insulating films HR102_1 is higher than the disposition density of the holes for the insulating films HR1. The holes for the insulating films HR102_1 may be joined. Ions reflected in the multi-stage step part STP1 mostly remain inside the holes for the insulating films HR102_1, and the erroneous etching of the sacrificial layers 6a can be prevented.

Thereafter, the insulating films HR1 are embedded in the holes for the insulating films HR1, and the insulating films HR102_1 are embedded in the holes for the insulating films HR102_1. The sacrificial layers 6a are removed, and the conductive layers 6 are embedded in gaps formed by removing the sacrificial layers 6a in a state where the insulating films HR1 and the insulating films HR102_1 function as the structural reinforcing materials.

At that time, since the erroneous etching of the sacrificial layers 6a can be prevented, pattern defects in the corresponding conductive layers 6 can be prevented.

In the multi-stage boundary region MBR2, a plurality of insulating films HR102_2 are planarly joined and disposed. The plurality of insulating films HR102_2 may be disposed so as to be arrayed in the grid shape in the XY direction in the multi-stage boundary region MBR2. Each insulating film HR102_2 may be joined with another insulating film HR102_2 adjacent in the XY direction as a partially continuous film. Thus, the plurality of insulating films HR102_2 are joined and disposed so as to cover the multi-stage step part STP4.

Among the plurality of insulating films Hr102_2 illustrated in FIG. 8, a surface on the +Z side of the insulating film HR102_2 on the +X side forms a part of the terrace part TER4, a surface on the +Z side of the insulating film HR102_2 on the −X side forms a part of the terrace part TER5, and a surface on the −X side of the insulating film HR102_2 at the center in the X direction forms the multi-stage step part STP4. While the multi-stage step part STP4 extends in the YZ direction, the extension surface on the −Z side thereof is mostly positioned within the insulating films HR102_2.

That is, the structure is such that the multi-stage step part STP4 and the vicinity of the extension surface are mostly filled with the insulating films HR102_2. This structure is suitable for preventing pattern defects in the conductive layers 6.

For example, in manufacturing, the stacked body SSTa in which the sacrificial layers 6a and the insulating layers 7 are alternately and repeatedly stacked is formed, and the multi-stage step part STP4 in the staircase structure is formed by applying a staircase working process. Thereafter, by a dry-etching process, holes for the insulating films HR1 are formed in the terrace part, and holes for the insulating films HR102_2 are formed in the multi-stage step part STP4.

At that time, the disposition density of the holes for the insulating films HR102_2 is higher than the disposition density of the holes for the insulating films HR1. The holes for the insulating films HR102_2 can be joined. Ions reflected in the multi-stage step part STP4 mostly remain inside the holes for the insulating films HR102_2, and the erroneous etching of the sacrificial layers 6a can be prevented.

Thereafter, the insulating films HR1 are embedded in the holes for the insulating films HR1, and the insulating films HR102_2 are embedded in the holes for the insulating films HR102_2. The sacrificial layers 6a are removed, and the conductive layers 6 are embedded in gaps formed by removing the sacrificial layers 6a in a state where the insulating films HR1 and the insulating films HR102_2 function as the structural reinforcing materials.

At that time, since the erroneous etching of the sacrificial layers 6a can be prevented, pattern defects in the corresponding conductive layers 6 can be prevented.

In this way, in the semiconductor storage device 101, the disposition density of the insulating films HR102 in the vicinity of the multi-stage step parts STP is higher than that of the insulating films HR1 in the terrace parts TER. The structure is such that the multi-stage step part STP and the vicinity of the extension surface are filled with the insulating films HR102. This structure is suitable for preventing pattern defects in the conductive layers 6. Thus, it is possible to provide a semiconductor storage device 101 in which the staircase structure SBS can be more appropriately formed.

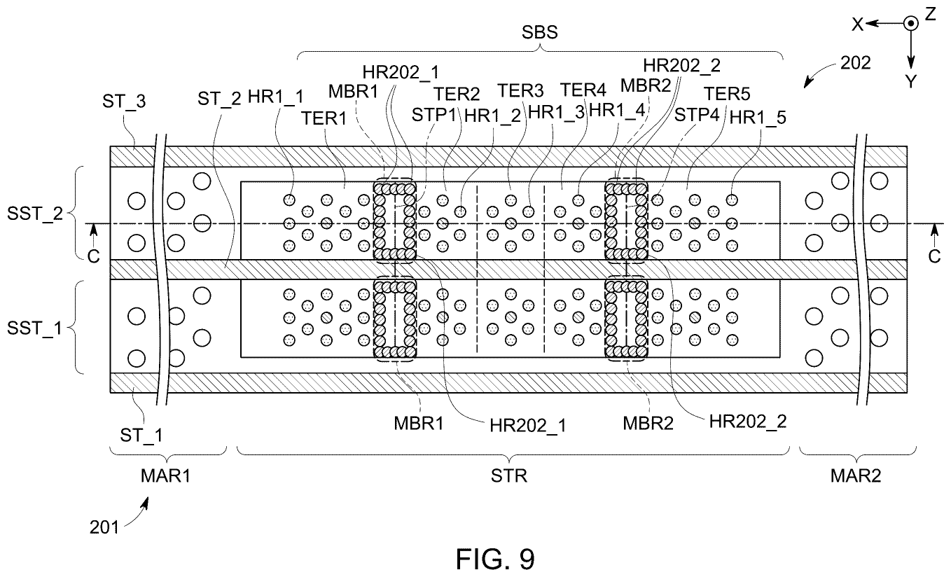

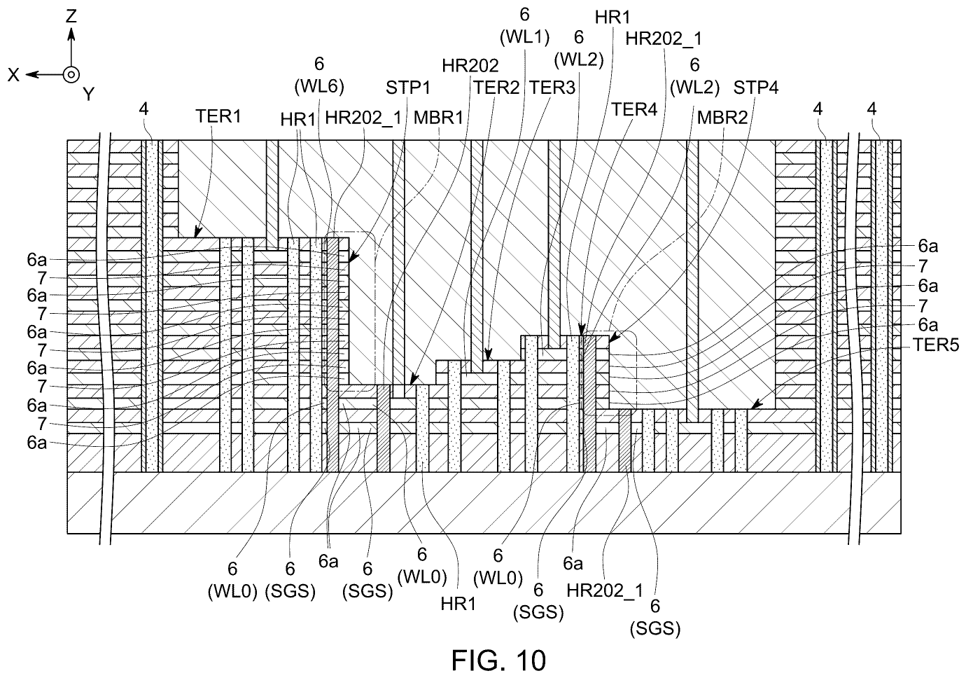

Alternatively, as a second modification of the embodiment, in a memory cell array 202 of a semiconductor storage device 201, as illustrated in FIG. 9 and FIG. 10, a plurality of insulating films HR202 may be joined and disposed in an annular shape in the multi-stage boundary regions MBR. FIG. 9 is an XY plan view illustrating the staircase structure SBS in the second modification of the embodiment. FIG. 10 is an XZ sectional view illustrating the staircase structure SBS in the second modification of the embodiment, and illustrates an XZ cross section in the case of cutting FIG. 9 on a C-C line.

In the multi-stage boundary region MBR1, a plurality of insulating films HR202_1 are joined and disposed in annular shape. The plurality of insulating films HR202_1 may be arrayed along a boundary of the multi-stage boundary region MBR1. Each insulating film HR202_1 may be joined with another insulating film HR202_1 adjacent in the XY direction as a partially continuous film. Thus, the plurality of insulating films HR202_1 are joined and disposed so as to surround the multi-stage step part STP1. The plurality of insulating films HR202_1 may be arrayed in a roughly rectangular shape with the Y direction as the longitudinal direction, surrounding the multi-stage step part STP1 in the XY planar view.

In the multi-stage boundary region MBR1 illustrated in FIG. 10, the insulating films HR202_1 extending in the Z direction are disposed respectively on a +X side end and a −X side end, and a stacked structure in which the sacrificial layers 6a and the insulating layers 7 are alternately stacked is disposed between the insulating films HR202_1 on the +X side and the insulating films HR202_1 on the −X side. A surface on the +Z side of the insulating film HR202_1 on the +X side and a surface on the +Z side of a part on the +X side of the stacked structure form a part of the terrace part TER1. A surface on the +Z side of a part on the −X side of the stacked structure and a surface on the +Z side of the insulating film HR202_1 on the −X side form a part of the terrace part TER2. A surface on the −X side of a part at the center in the X direction of the stacked structure forms the multi-stage step part STP1. While the multi-stage step part STP1 extends in the YZ direction, the extension surface on the −Z side thereof is positioned within the stacked structure. The stacked structure is surrounded by the plurality of insulating films HR202_1 in the XY planar view, and is isolated from the conductive layers 6 on the outer side in the XY direction via the insulating films HR202_1 (see FIG. 9).

That is, the structure is such that the multi-stage step part STP1 and the vicinity of the extension surface are positioned within the stacked structure surrounded by the plurality of insulating films HR202_1. This structure is suitable for preventing pattern defects in the conductive layers 6.

For example, in manufacturing, the stacked body SSTa in which the sacrificial layers 6a and the insulating layers 7 are alternately and repeatedly stacked is formed, and the multi-stage step part STP1 in the staircase structure is formed by applying a staircase working process. Thereafter, by a dry-etching process, holes for the insulating films HR1 are formed in the terrace part, and holes for the plurality of insulating films HR202_1 are formed in the vicinity of the multi-stage step part STP1.

At that time, the holes for the plurality of insulating films HR202_1 are joined and disposed so as to surround the multi-stage step part STP1 from the outer side in the XY direction. Ions reflected in the multi-stage step part STP1 mostly remain inside a region surrounded by the holes for the plurality of insulating films HR202_1, and the erroneous etching of the sacrificial layers 6a on the outer side in the XY direction of the holes for the plurality of insulating films HR202_1 can be prevented.

Thereafter, the insulating films HR1 are embedded in the holes for the insulating films HR1, and the insulating films HR202_1 are embedded in the holes for the insulating films HR202_1. The sacrificial layers 6a on the outer side in the XY direction of the plurality of insulating films HR202_1 are removed. The conductive layers 6 are embedded in gaps formed by removing the sacrificial layers 6a on the outer side in the XY direction of the plurality of insulating films HR202_1 in a state where the insulating films HR1 and the insulating films HR202_1 function as the structural reinforcing materials.

At that time, since the erroneous etching of the sacrificial layers 6a on the outer side in the XY direction of the plurality of insulating films HR202_1 can be prevented, pattern defects in the corresponding conductive layers 6 can be prevented.

Note that even though the sacrificial layers 6a on the inner side in the XY direction of the plurality of insulating films HR202_1 may be etched, these sacrificial layers 6a are not replaced with conductive layers 6 so that pattern defects in the conductive layers 6 do not result.

In the multi-stage boundary region MBR2, insulating films HR202_2 extending in the Z direction are disposed respectively on a +X side end and a −X side end, and a stacked structure in which the sacrificial layers 6a and the insulating layers 7 are alternately stacked is disposed between the insulating films HR202_2 on the +X side and the insulating films HR202_2 on the −X side. A surface on the +Z side of the insulating film HR202_2 on the +X side and a surface on the +Z side of a part on the +X side of the stacked structure form a part of the terrace part TER4. A surface on the +Z side of a part on the −X side of the stacked structure and a surface on the +Z side of the insulating film HR202_2 on the −X side form a part of the terrace part TER5. A surface on the −X side of a part at the center in the X direction of the stacked structure forms the multi-stage step part STP4. While the multi-stage step part STP4 extends in the YZ direction, the extension surface on the −Z side thereof is positioned within the stacked structure. This stacked structure is surrounded by the plurality of insulating films HR202_2 in the XY planar view and is isolated from the conductive layers 6 on the outer side in the XY direction via the insulating films HR202_2 (see FIG. 9).

That is, the multi-stage step part STP4 and the vicinity of (region adjacent) the extension surface are positioned within the stacked structure and surrounded by the plurality of insulating films HR202_2. This structure is suitable for preventing pattern defects of the conductive layers 6.

For example, in manufacturing, the stacked body SSTa in which the sacrificial layers 6a and the insulating layers 7 are alternately and repeatedly stacked is formed, and the multi-stage step part STP4 in the staircase structure is formed by applying a staircase working process. Thereafter, by a dry-etching process, holes for the insulating films HR1 are formed in the terrace part, and holes for the plurality of insulating films HR202_2 are formed in the vicinity of the multi-stage step part STP4.

At that time, the holes for the plurality of insulating films HR202_2 can be joined and disposed so as to surround the multi-stage step part STP4 from the outer side in the XY direction. Ions reflected in the multi-stage step part STP4 mostly remain inside a region surrounded by the holes for the plurality of insulating films HR202_2, and the erroneous etching of the sacrificial layers 6a on the outer side in the XY direction of the holes for the plurality of insulating films HR202_2 can be prevented.

Thereafter, the insulating films HR1 are embedded in the holes for the insulating films HR1, and the insulating films HR202_2 are embedded in the holes for the insulating films HR202_2. The sacrificial layers 6a on the outer side in the XY direction of the plurality of insulating films HR202_2 are removed. The conductive layers 6 are embedded in gaps formed by removing the sacrificial layers 6a on the outer side in the XY direction of the plurality of insulating films HR202_2 in a state where the insulating films HR1 and the insulating films HR202_2 function as the structural reinforcing materials.

At that time, since the erroneous etching of the sacrificial layers 6a on the outer side in the XY direction of the plurality of insulating films HR202_2 can be prevented, pattern defects in corresponding conductive layers 6 can be prevented.

Note that even though the sacrificial layers 6a on the inner side in the XY direction of the plurality of insulating films HR202_2 may be etched, these sacrificial layers 6a are not replaced with conductive layers 6 so that pattern defects in the conductive layers 6 do not result.

In this way, in the semiconductor storage device 201, the plurality of insulating films HR202_1 are joined and disposed so as to surround the multi-stage step part STP1. The structure is such that the multi-stage step part STP and the vicinity of the extension surface are positioned within the stacked structure on the inner side in the XY direction of the plurality of insulating films HR202_1. This structure is suitable for preventing pattern defects in the conductive layers 6. Thus, it is possible to provide the semiconductor storage device 201 in which the staircase structure SBS can be more appropriately formed.

While certain embodiments have been described, these embodiments have been presented by way of example only, and are not intended to limit the scope of the disclosure. Indeed, the novel devices and methods described herein may be embodied in a variety of other forms; furthermore, various omissions, substitutions and changes in the form of the embodiments described herein may be made without departing from the spirit of the disclosure. The accompanying claims and their equivalents are intended to cover such forms or modification as would fall within the scope and spirit of the disclosure.

What is claimed is

1. A semiconductor storage device, comprising:
a stacked body of conductive layers stacked in a stacking direction with insulating layers in between, the stacked body including a staircase structure in a central region along a longitudinal direction;
a first insulating film extending through the stacked body in the stacking direction, the first insulating film being in a terrace part of the staircase structure; and
a second insulating film in a region of the stacked body including a step part of the staircase structure, the second insulating film extending through the stacked body in the stacking direction and having a minimum plane width that is greater than a minimum plane width of the first insulating film.

2. The semiconductor storage device of claim 1, wherein the second insulating film has a plane width equal to a plane width of the terrace part.

3. The semiconductor storage device of claim 1, wherein the second insulating film has a maximum plane width greater than a maximum plane width of the first insulating film.

4. The semiconductor storage device of claim 1, wherein the second insulating film covers the step part in the region.

5. The semiconductor storage device of claim 1, wherein the second insulating films is generally rectangular in a plan view.

6. The semiconductor storage device of claim 1, further comprising:
a memory cell array area adjacent to an end of the staircase structure in the longitudinal direction.

7. The semiconductor storage device of claim 1, wherein a dimension in the stacking direction of the step part is greater than a disposition pitch of the conductive layers in the stacking direction of the stacked body.

8. The semiconductor storage device of claim 7, wherein the dimension of the step part in the stacking direction is an integral multiple of the disposition pitch of the conductive layers in the stacked body and at least twice the disposition pitch.

9. A semiconductor storage device, comprising:
a stacked body of conductive layers stacked in a stacking direction with insulating layers in between, the stacked body including a staircase structure in a central region along a longitudinal direction;
a plurality of first insulating films extending through the stacked body in the stacking direction, the first insulating films being in a terrace part of the staircase structure; and
a plurality of second insulating films in a region of the stacked body including a step part of the staircase structure, the second insulating films extending through the stacked body in the stacking direction and having a disposition density higher than a disposition density of the plurality of first insulating film.

10. The semiconductor storage device of claim 9, wherein two or more of the one or more second insulating films are joined.

11. The semiconductor storage device of claim 9, wherein two or more of the second insulating films are joined and cover the step part in the region.

12. The semiconductor storage device of claim 9, wherein the second insulating films are disposed in annular shape around a perimeter of the region.

13. The semiconductor storage device of claim 12, wherein the second insulating films are joined to adjacent second insulating films in the plurality of second insulating films.

14. The semiconductor storage device of claim 9, wherein the plurality of second insulating films surround the step part in the region.

15. The semiconductor storage device of claim 9, further comprising:
a memory cell array area adjacent to an end of the staircase structure in the longitudinal direction.

16. The semiconductor storage device of claim 9, wherein each second insulating film has a maximum plane width equal to a maximum plane width of the plurality of first insulating films.

17. A semiconductor storage device, comprising:
a stacked body of conductive layers stacked in a stacking direction with insulating layers in between, the stacked body including a staircase structure in a central region along a longitudinal direction and a memory cell array structure in an end region along the longitudinal direction;
a plurality of first insulating films in a terrace region of the staircase structure, the first insulating films extending through the stacked body in the stacking direction; and
a second insulating film in a step part region of the staircase structure, the second insulating film extending through the stacked body in the stacking direction and having a minimum plane width that is greater than a minimum plane width of the first insulating film.

18. The semiconductor storage device of claim 17, wherein the second insulating film has a plane width equal to a plane width of the terrace part.

19. The semiconductor storage device of claim 17, wherein the second insulating film covers the step part region.

20. The semiconductor storage device of claim 17, wherein the plurality of first insulating films are arranged in a regular array pattern.
